(19) United States
(12) Patent Application Publication
(10) Pub. No.: US 2011/0233786 A1
(43) Pub. Date: Sep. 29, 2011

(54) SEMICONDUCTOR DEVICE AND METHOD FOR MANUFACTURING THE SAME

(76) Inventors: Soichi HOMMA, Kawasaki-shi (JP); Masayuki MIURA, Tokyo (JP); Taku KAMOTO, Yokohama-shi (JP); Satoshi HONGO, Tokyo (JP)

(21) Appl. No.: 13/044,958

(22) Filed: Mar. 10, 2011

(30) Foreign Application Priority Data
Mar. 24, 2010 (JP) 2010-068407

(51) Int. Cl. H01L 23/28; H01L 21/50; H01L 21/56

(52) U.S. Cl. 257/773; 438/113; 438/127; 257/E21.499; 257/E21.502; 257/E23.116

(57) ABSTRACT

According to an embodiment, a separation layer and a wiring layer having an organic insulating film formed of a resin material and a metal wiring are sequentially formed on a support substrate. Regions of the organic insulating film corresponding to dicing regions are removed. Plural semiconductor chips are mounted on the wiring layer. A sealing resin layer is formed on the separation layer. The sealing resin layer is formed to cover edge surfaces of the device forming regions. The support substrate is separated from a resin sealing body having the wiring layer, the plural semiconductor chips and the sealing resin layer. The resin sealing body is cut according to the dicing regions to cingulate a structure configuring a semiconductor device.

### CROSS-REFERENCE TO RELATED APPLICATION

This application is based upon and claims the benefit of priority from Japanese Patent Application No. 2010-068407, filed on Mar. 24, 2010; the entire contents of which are incorporated herein by reference.

### FIELD

Embodiments described herein relate generally to a semiconductor device and a method for manufacturing the same.

### BACKGROUND

Since portable electronic equipment such as cellular phones are being manufactured smaller and thinner in size, the area of a semiconductor device mounting region is becoming smaller and the height is becoming smaller too. Therefore, a so-called double-sided mount type semiconductor device, in which semiconductor chips are mounted on both sides of a single substrate, is used. For example, the double-sided mount type semiconductor device is manufactured as follows. First, a wiring layer is formed on a support substrate, and a semiconductor chip is mounted on the front surface of the wiring layer. Then, the support substrate is removed, and another semiconductor chip is mounted on the rear surface of the wiring layer.

In the above-described semiconductor device manufacturing process, it is demanded that the support substrate is removed easily in a short time without causing a defect in the semiconductor chip or the wiring layer while it is made possible to repeatedly use the support substrate. As a method of removing the support substrate, there is a known method that uses a separation layer formed of a thermoplastic resin. The separation layer formed of the thermoplastic resin is formed on the support substrate, and a wiring layer having an organic insulating film and a metal wiring is formed on it. After the semiconductor chip is mounted on the wiring layer and sealed with a resin, shearing is conducted while heating the separation layer to separate a structure comprised of the wiring layer, the semiconductor chip and the sealing resin layer from the support substrate.

A method of shearing the separation layer while heating has an advantage that the support substrate can be removed easily in comparison with, for example, a method that melts or burns the separation layer at a high temperature. In addition, a thermal adverse effect on the semiconductor chip or the wiring layer is small. But, when the separation layer formed of the thermoplastic resin is sheared to separate the support substrate, a stress concentrates on the edge portions of the wiring layer, and the wiring layer might peel off. In addition, when the wiring layer and the sealing resin are cut off together to singulate a semiconductor device after plural semiconductor chips are mounted on the wiring layer and resin-sealed, the wiring layer might be damaged. It also causes peeling of the wiring layer.

### BRIEF DESCRIPTION OF THE DRAWINGS

FIGS. 1A to 1D are sectional views showing from a separation layer forming step to a sealing resin layer forming step in a semiconductor device manufacturing method according to a first embodiment.

FIGS. 2A to 2C are sectional views showing from a support substrate separating step to a resin sealing body cutting step in the semiconductor device manufacturing method according to the first embodiment.

FIGS. 3A to 3C are sectional views showing in a magnified fashion from a separation layer forming step to an organic insulating film forming step in the semiconductor device manufacturing method according to the first embodiment.

FIGS. 4A to 4C are sectional views showing in a magnified fashion a wiring layer forming step in the semiconductor device manufacturing method according to the first embodiment.

FIGS. 5A to 5C are sectional views showing in a magnified fashion from a semiconductor chip mounting step to a sealing resin layer forming step in the semiconductor device manufacturing method according to the first embodiment.

FIG. 6 is a view showing the entire shape of the sealing resin layer according to the first embodiment.

FIGS. 7A and 7B are views showing an example of an alignment portion to be formed on the sealing resin layer.

FIGS. 8A and 8B are views showing another example of the alignment portion to be formed on the sealing resin layer.

FIGS. 9A and 9B are views showing still another example of the alignment portion to be formed on the sealing resin layer.

FIGS. 10A to 10C are sectional views showing in a magnified fashion from a support substrate separating step to a separation layer removing step in the semiconductor device manufacturing method according to the first embodiment.

FIG. 11 is a sectional view showing a semiconductor package using the double-sided mount type semiconductor device manufactured according to the first embodiment.

FIGS. 12A and 12B are sectional views showing a step of manufacturing a double-sided mount type semiconductor device by using the semiconductor device manufactured according to the first embodiment.

FIG. 13 is a sectional view showing a semiconductor package using the one-sided mount type semiconductor device manufactured according to the first embodiment.

FIGS. 14A and 14B are sectional views showing another mounting step of the semiconductor chip in the semiconductor device manufacturing method according to the first embodiment.

FIGS. 15A to 15C are sectional views showing from a separation layer forming step to a mixed layer removing step in the semiconductor device manufacturing method according to a second embodiment.

FIGS. 16A to 16C are sectional views showing from a sealing resin layer forming step to a support substrate separating step in the semiconductor device manufacturing method according to the second embodiment.

### DETAILED DESCRIPTION

According to one embodiment, there is provided a method for manufacturing a semiconductor device, comprising forming on a support substrate a separation layer formed of a resin material; forming on the separation layer a wiring layer which is comprised of an organic insulating film having plural device forming regions and regions corresponding to dicing regions for dividing the plural device forming regions, and a metal wiring which is formed on the plural device forming regions of the organic insulating film; removing the regions corresponding to the dicing regions of the organic insulating film; mounting plural semiconductor chips on the wiring layer to arrange them on the plural device forming regions; forming a sealing resin layer for sealing at least part of each of the plural semiconductor chips on the separation layer to cover an edge surface of each of the plural device forming regions of the wiring layer; separating the support substrate from a resin sealing body having the wiring layer, the plural semiconductor chips and the sealing resin layer; and cutting the resin sealing body according to the dicing regions to singilate a structure having the wiring layer, the semiconductor chip and the sealing resin layer.

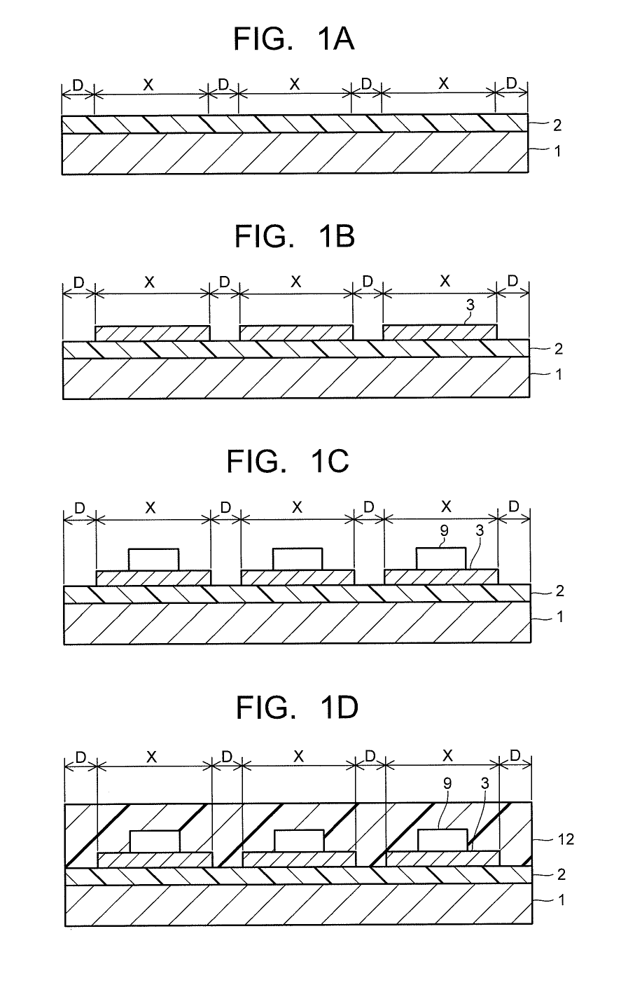

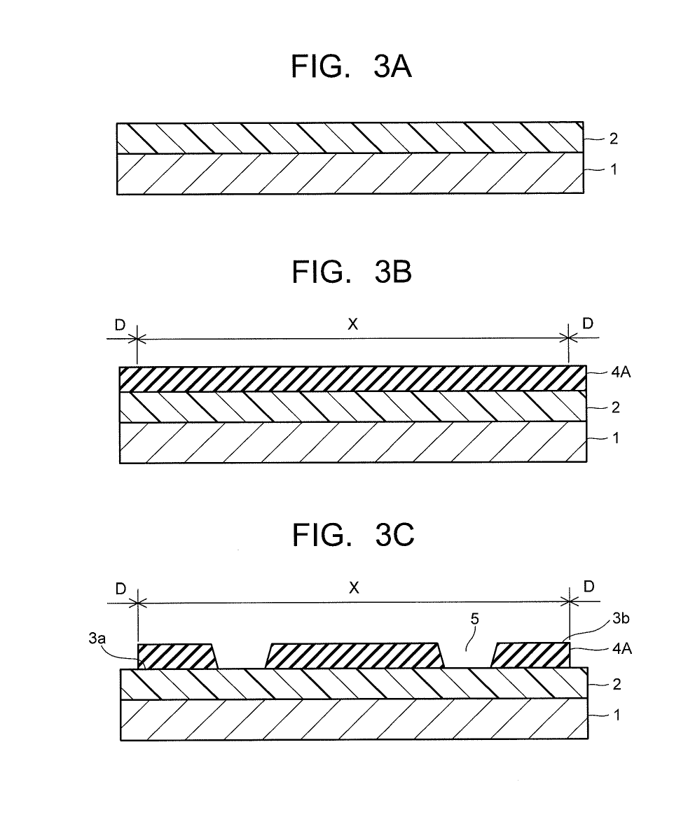

A semiconductor device and a manufacturing method of the semiconductor device according to embodiments are described below with reference to the drawings. FIGS. 1A to 10C are views showing a manufacturing method of a semiconductor device according to a first embodiment. In the first embodiment, an 8-inch Si wafer is prepared as a support substrate 1, and a 5-μm thick separation layer 2 is formed on it as shown in FIG. 1A and FIG. 3A. The support substrate 1 may be a glass substrate, a sapphire substrate, a resin substrate or the like. The support substrate 1 has plural device forming regions X and regions D corresponding to dicing regions of a resin sealing body described later. The dicing regions are provided to divide the plural device forming regions X of the resin sealing body.

The separation layer 2 is formed of a resin material. The resin material forming the separation layer 2 is preferably a thermoplastic resin such as polyethylene, polypropylene, polystyrene, aclylonitrile styrene resin, aclylonitrile butadiene styrene resin, methacrylate resin, polyamide, polyacetal, polyethylene terephthalate, ultra high molecular weight polyethylene, polybutylene terephthalate, methylpentene, polycarbonate, polyphenylene sulfide, polyether ether ketone, liquid crystalline polymer, polytetrafluoroethylene, polyether imide, polyalylate, polysulfone, polyether sulfone, polyamide imide, cellulose resin, polyimide, etc. The separation layer 2 has preferably a thickness in a range from 1 to 20 μm. When the separation layer 2 has a thickness of less than 1 μm, there is a possibility that the support substrate 1 cannot be separated well. Even when the separation layer 2 is formed thick, its thickness of about 20 μm is sufficient. When the separation layer 2 is formed to have a larger thickness, its manufacturing cost increases. The thickness of the separation layer 2 is preferably determined depending on the method of separating the support substrate 1.

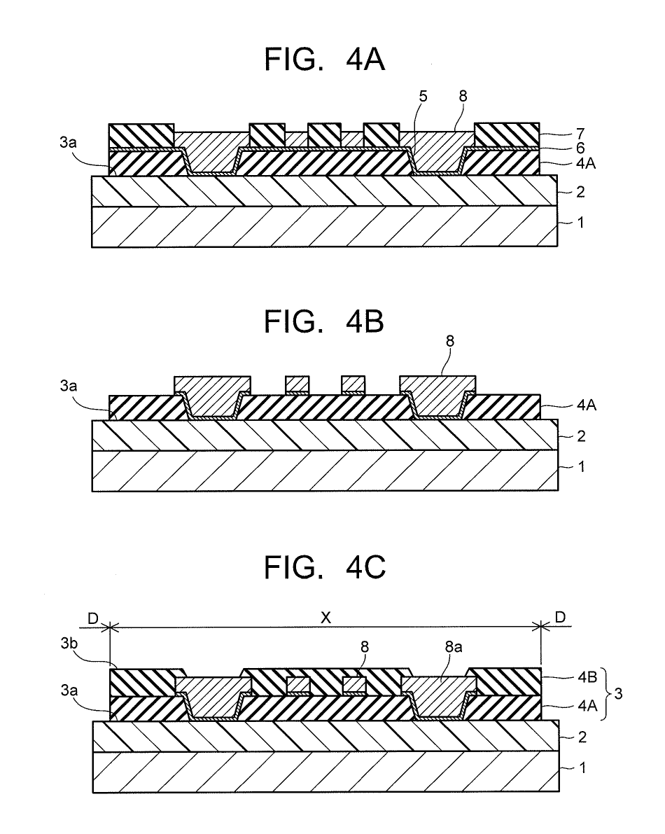

Then, wiring layers 3 are formed on the separation layer 2 as shown in FIG. 1B. The wiring layers 3 are respectively formed on the plural device forming regions X. A forming step of the wiring layers 3 is described in detail with reference to FIGS. 3A to 3C and FIGS. 4A to 4C. As shown in FIG. 3B, a first organic insulating film 4A which configures the wiring layer 3 is formed on the separation layer 2. For example, a polyimide resin having a thickness of about 3 μm is used as the first organic insulating film 4A. The first organic insulating film 4A may be a polybenzoxazole resin film, a phenol resin film, an acryl resin film or the like. The first organic insulating film 4A is also determined to have an appropriate thickness. The first organic insulating film 4A has the plural device forming regions X and the regions D corresponding to the dicing regions for dividing the device forming regions X.

As shown in FIG. 3C, portions of the first organic insulating film 4A in the regions D are partly removed. Thus, the wiring layers 3 can be suppressed from being peeled or damaged in the separating step of the support substrate 1 or the cutting step of the resin sealing body. The first organic insulating film 4A is then undergone the exposure and development treatment to form opening portions 5 having a diameter of, for example, 20 μm at a pitch of 40 μm. The opening portions 5 are formed in correspondence with connection pads which are arranged on a first surface (surface separated from the support substrate 1) 3a of the wiring layers 3. The opening portions 5 have a shape that their outer shape becomes smaller from a second surface 3b on the side opposite to the first surface 3a toward the first surface 3a. For example, it is preferable that the opening portions 5 have a shape that the opening diameter on the first surface 3a is smaller than that of the second surface 3b by a range of 10 to 50%. Thus, the wiring layers 3 can be suppressed from being peeled or damaged in a subsequent step.

A metal wiring which configures the wiring layers 3 is then formed. As a seed layer 6 for plating, for example, a Ti film having a thickness of 0.05 μm and a Cu film having a thickness of 0.1 μm are formed as shown in FIG. 4A. A resist is applied in a thickness of 5 μm and the exposure and development treatment is performed to form a resist film 7 having opening portions which become metal wiring forming regions. And, electrolytic Cu plating is performed with the seed layer 6 used as an electrode to form a metal wiring 8 having, for example, a width of 3 μm. The metal wiring 8 is formed to fill the opening portions 5 of the first organic insulating film 4A. The metal wiring 8 is not limited to Cu but may be formed of Al, Ag, Au or the like.

As shown in FIG. 4B, the resist film 7 is removed, and the Cu film and the Ti film of the seed layer 6 exposed on the first organic insulating film 4A are removed by etching. A mixture of sulfuric acid and oxygenated water, or the like is used for etching of the Cu film, and a mixture of ammonia water and oxygenated water, or the like is used for etching of the Ti film. Similar to the forming step of the first organic insulating film 4A, a second organic insulating film 4B is formed with openings formed at portions corresponding to the connection pads on the side of the second surface 3b of the wiring layers 3 as shown in FIG. 4C. Openings having a diameter of 20 μm are also formed at a pitch of 40 μm in the second organic insulating film 4B to expose the metal wiring 8 in the openings. The second organic insulating film 4B is formed of an organic resin material similar to the first organic insulating film 4A.

The second organic insulating film 4B is formed to have the same shape as the first organic insulating film 4A. Therefore, the wiring layers 3 which are comprised of the metal wiring 8 and the first and second organic insulating films 4A and 4B are present in the device forming region X only as shown in FIG. 4C. The organic insulating films 4A and 4B are not present in the regions D (regions corresponding to the dicing regions). The metal wiring 8 has connection portions (through electrodes) 8a formed in the opening portions 5. The connection portions 8a have a shape that the outer shape becomes smaller from the second surface (surface on the side opposite to the surface separated from the support substrate 1) 3b toward the first surface (the surface separated from the support substrate 1) 3a of the wiring layers 3 according to the shape of the opening portions 5. The connection portions 8a are preferable that an exposed diameter on the first surface 3a is smaller than that of the second surface 3b by 10 to 50%.

The connection portions 8a of the metal wiring 8 are formed to penetrate through the organic insulating film 4 and exposed to the first and second surfaces 3a and 3b of the wiring layers 3. Exposed portions of the connection portions 8a on the side of the second surface 3b function as the connection pads to the semiconductor chips mounted on the wiring layers 3. The exposed portions of the connection portions 8a on the side of the first surface 3a function as the connection pads to another semiconductor chip, wiring board or the like. FIGS. 4A to 4C show the single-layer metal wiring 8, but the wiring layers 3 may be configured of a double-or-more layer metal wiring. The organic insulating film 4 is formed according to the number of layers of the metal wiring 8. Even in such a case, the organic insulating film 4 is removed from the regions D. It is desirable that the wiring layers 3 having the organic insulating films 4 stacked have a thickness of 50 μm or less, and preferably 30 μm or less.

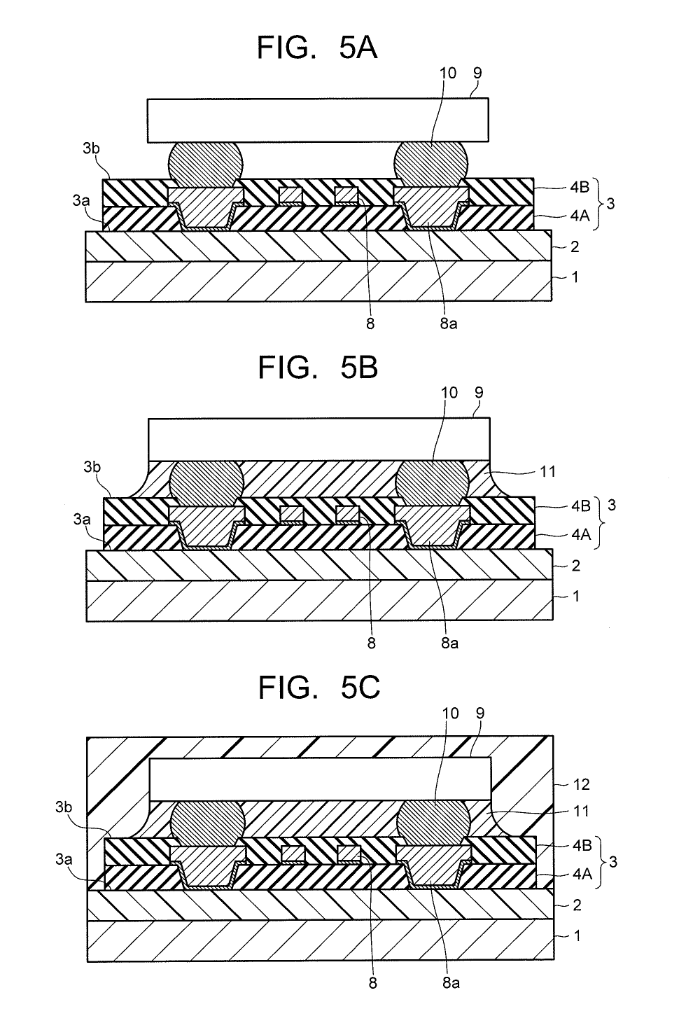

As shown in FIG. 1C, plural semiconductor chips 9 are mounted on the wiring layers 3. The semiconductor chips 9 are arranged on the wiring layers 3 formed in the device forming regions X. The mounting step of the semiconductor chips 9 is described in detail with reference to FIGS. 5A to 5C. An example of applying flip chip (FC) connection for connection of the wiring layers 3 and the semiconductor chips 9 is described. The each semiconductor chip 9 has metal bumps 10 formed of a Sn—Ag alloy or the like. The metal bumps 10 may be formed of Sn, Au, Ag, Cu, Bi, In, Ge, Ni, Pd, Pt, Pb, or an alloy or mixture of them. The metal bumps 10 are formed at a pitch of 40 μm to correspond with the connection portions 8a and have a diameter of 20 μm.

The semiconductor chip 9 is undergone FC mounting such that the metal bumps 10 are connected to portions of the connection portions 8a exposed on the side of the second surface 3b as shown in FIG. 5A. The semiconductor chips 9 are mounted on the wiring layers 3 corresponding to the plural device forming regions X. The metal bumps 10 may be connected after forming a Ni/Pd/Au laminated film or the like as a barrier metal on the exposed portions of the connection portions 8a. The FC mounting is performed as follows. The semiconductor chips 9 having flux coated on the metal bumps 10 is mounted on the wiring layer 3 by a flip-chip bonder and places them in a reflow furnace to connect them. The flux is then removed by a cleaning fluid. When the flux is not used, the surface oxidized film of the metal bumps 10 is removed by plasma or the like, and the flip chip bonder may be used to connect by pulse heating.

The gap between the semiconductor chip 9 and the wiring layer 3 after the FC connection is filled with an underfill resin 11 as shown in FIG. 5B. Then, a sealing resin layer 12 is formed on the second surface 3b of the wiring layer 3 as shown in FIG. 1D and FIG. 5C. The sealing resin layer 12 is formed to cover at least part of the semiconductor chip 9 as well as the wiring layer 3. The sealing resin layer 12 is formed by molding or the like. FIG. 1D and FIG. 5C show a state that the semiconductor chip 9 is entirely sealed by the sealing resin layer 12. The sealing resin layer 12 may be formed to seal partly the semiconductor chip 9 (e.g., the side surface of the semiconductor chip 9 is covered, and the rear surface of the semiconductor chip 9 is exposed).

As shown in FIG. 1D, the sealing resin layer 12 is formed not only on the second surface 3b of the wiring layers 3, but also on the separation layer 2. The sealing resin layer 12 is formed on the separation layer 2 of the support substrate 1 to collectively seal the plural semiconductor chips 9 mounted on the plural wiring layers 3. Therefore, the sealing resin layer 12 is also formed between the neighboring wiring layers 3 on the separation layer 2. In other words, the sealing resin layer 12 is also formed on the regions D where the organic insulating film 4 is removed in the forming step of the wiring layers 3. Thus, the edge surfaces (side surfaces) of the wiring layers 3 are covered by the sealing resin layer 12. By covering the edge surfaces of the wiring layers 3 by the sealing resin layer 12, the wiring layers 3 can be suppressed from being peeled or damaged in a subsequent step.

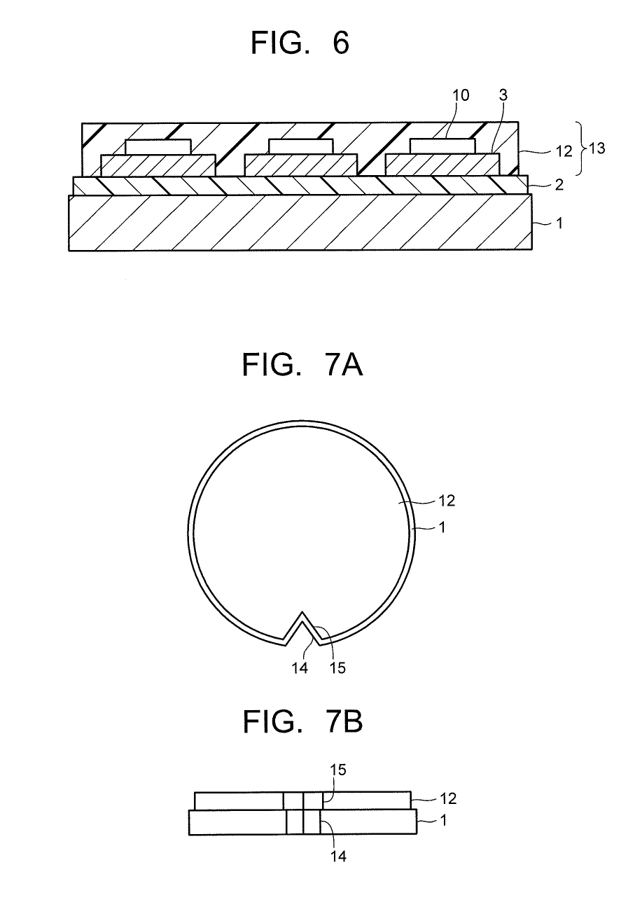

It is preferable that the entire shape (outer shape) of the sealing resin layer 12 has the shape as shown in FIG. 6. In other words, it is preferable that the sealing resin layer 12 is formed to have its outer periphery smaller than that of the separation layer 2. The sealing resin layer 12 is formed to cover the edge surfaces of the wiring layers 3, so that the outer periphery of the sealing resin layer 12 is located outside of the outer peripheries of the wiring layers 3 which are located at the outermost periphery. The outer periphery of the sealing resin layer 12 is positioned between the outer periphery of the organic insulating film 4 of the wiring layer 3 which is located at the outermost periphery and the outer periphery of the separation layer 2. For example, when the support substrate 2 is an 8-inch Si wafer, it is determined that the edge cut of the outer periphery of the separation layer 2 is 1 mm, the edge cut of the outer periphery of the sealing resin layer 12 is 2.5 mm, and the edge cut of the outer periphery of the organic insulating film 4 of the wiring layer 3 is 5 mm.

Thus, the forming regions of the wiring layers 3 according to the plural device forming regions X are made smaller than the sealing resin layer 12, and the forming region of the sealing resin layer 12 is made smaller than the separation layer 2, so that a stress concentration to the end portions of the wiring layers 3 in the separation step of the support substrate 2 is suppressed, and a stress concentration to the end portions of the sealing resin layer 12 is also suppressed. Therefore, the wiring layers 3 can be suppressed from being peeled or damaged. At the time of molding the sealing resin layer 12, the mold clamping surface of a mold is directly pushed against the exposed separation layer 2, and there is a possibility of causing flash that the molding resin leaks to the outer periphery, but it can be suppressed by lowering the modulus of elasticity of the thermoplastic resin forming the separation layer 2.

A resin sealing body 13 which has the plural wiring layers 3 and the semiconductor chips 9 and the sealing resin layer 12 is separated from the support substrate 1 and then cut off for singulation. To perform the step of fabricating the resin sealing body 13 only, it is preferable that the sealing resin layer 12 is formed with a cutout, a mark or the like (hereinbelow collectively called as the alignment portion) for alignment to identify a rotation direction of the resin sealing body 13. The cutout shape as the alignment portion includes a notch shape or an orientation flat shape. The method of forming the mark as the alignment portion includes a method of printing or marking a scratch or a dent on the sealing resin layer 12.

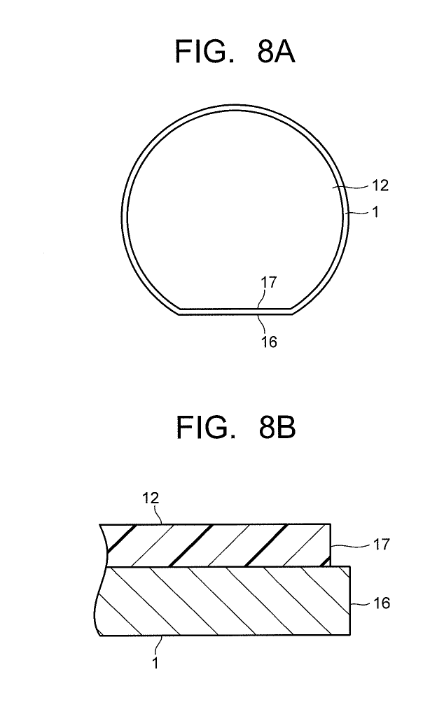

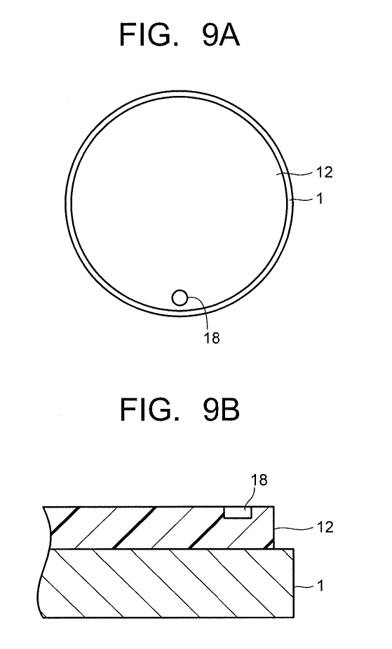

FIG. 7A and FIG. 7B show a notch 15 of the sealing resin layer 12 formed in correspondence with a notch 14 of the support substrate 1. FIG. 8A and FIG. 8B show an orientation flat 17 of the sealing resin layer 12 formed in correspondence with an orientation flat 16 of the support substrate 1. FIG. 9A and FIG. 9B show the sealing resin layer 12 with a recessed mark 18 formed as the alignment portion. FIG. 9A and FIG. 9B show the mark 18 having a round planar shape, but the planar shape of the mark 18 may be square, cross or the like. It is not shown in FIG. 9A and FIG. 9B but the mark 18 is formed in correspondence with the notch, the orientation flat or the like for alignment of the support substrate 1. The alignment portion such as the notch 15, the orientation flat 17 or the mark 18 is formed on the sealing resin layer 12, so that the resin sealing body 13 separated from the support substrate 1 can be aligned easily.

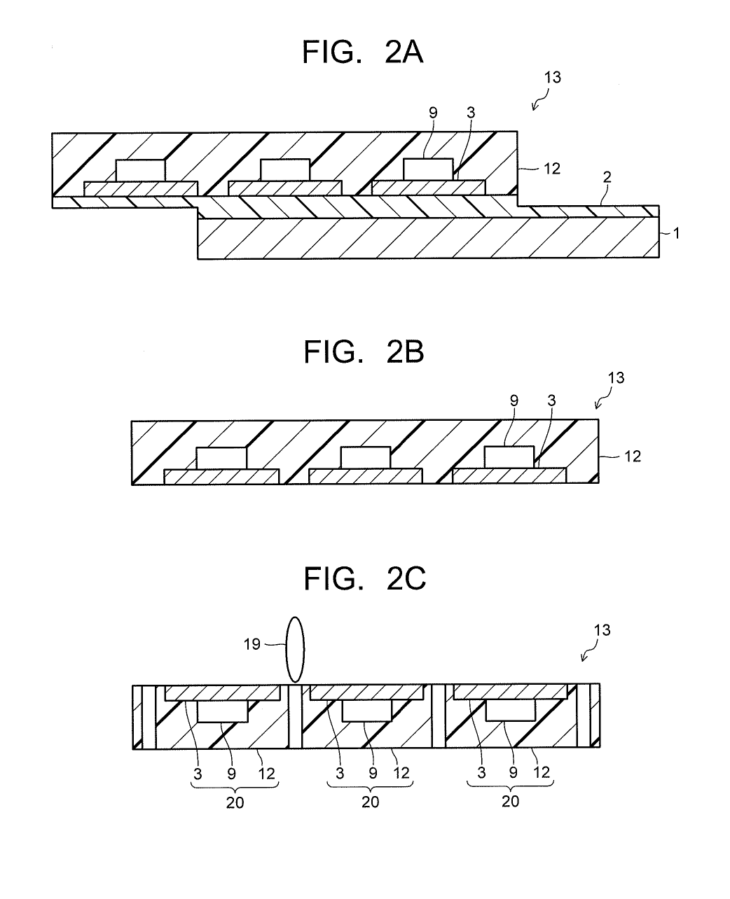

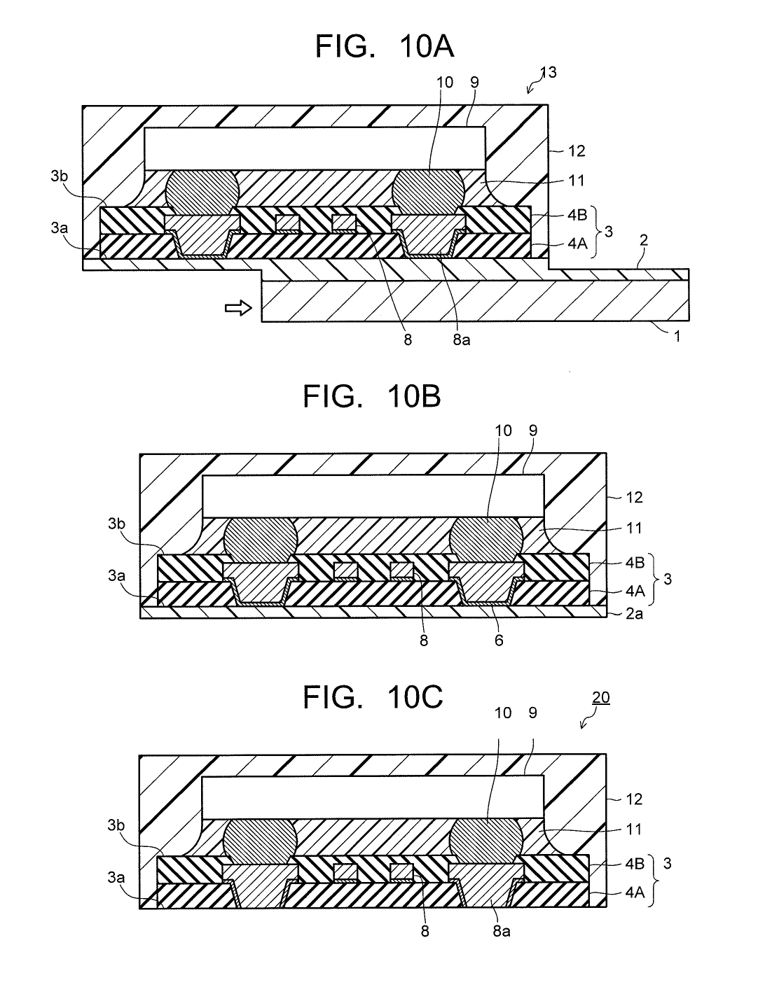

As shown in FIG. 2A and FIG. 10A, a laminated body having the support substrate 1 and the resin sealing body 13 which is formed on the support substrate 1 via the separation layer 2 is then heated to a prescribed temperature to soften the thermoplastic resin layer used as the separation layer 2, and the support substrate 1 and the resin sealing body 13 are also moved in a substantially parallel direction relative to each other. A shearing force generated between the support substrate 1 and the resin sealing body 13 is used to shear the softened separation layer 2, and the support substrate 1 is separated from the resin sealing body 13. At this time, in addition to the substantially parallel movement of the support substrate 1 and the resin sealing body 13, they are also moved in a vertical direction to some extent, so that the separation of the support substrate 1 can be promoted. For shearing the separation layer 2, the thickness of the separation layer 2 is preferably in a range of 10 to 20 μm.

For example, the heating temperature of the thermoplastic resin layer as the separation layer 2 is preferably in a range of 220 to 260° C. By heating at such temperatures, the support substrate 1 can be separated easily in a short time without causing a thermal damage to the semiconductor chips 9, deformation of FC connection portions or the wiring layers 3, or the like. The separated support substrate 1 can be used repeatedly. To facilitate the separation of the support substrate 1 and the resin sealing body 13 by the heating treatment, it is preferable that the thermoplastic resin forming the separation layer 2 has a viscosity of 100 Pa·s or less or a shear modulus of 100 kPa or less at 250° C.

When the support substrate 1 is separated by shearing the separation layer 2, a stress concentration to the edge surfaces of the wiring layers 3 at the time of shearing the separation layer 2 can be prevented because the edge surfaces of the individual wiring layers 3 are covered by the sealing resin layer 12 and the edge surfaces of the wiring layers 3 of the outermost periphery of the entire sealing resin layer 12 are also covered. In other words, the starting point of the stress concentration when the separation layer 2 is sheared becomes the sealing resin layer 12. In addition, a stress applied to the connection portions 8a can be reduced because the connection portions 8a exposed on the first surface 3a of the wiring layer 3 are formed to have the outer shape formed to become smaller from the second surface 3b toward the first surface 3a. Thus, the wiring layers 3 can be suppressed from being peeled or damaged. Therefore, the wiring is suppressed from being broken when the semiconductor device is undergone reflowing or TCT, and the semiconductor device having excellent reliability and durability can be provided.

The method of separating the support substrate 1 is not limited to the method that the separation layer 2 is sheared and the support substrate 1 is separated from the resin sealing body 13. For example, a Si wafer is used as the support substrate 1, the separation layer 2 is formed of a polyamide type thermoplastic resin, and they are placed with the Si wafer on the lower side on a hot plate and heated to 250° C. At 250° C., the polyamide type thermoplastic resin exceeds a glass transition point and becomes soft. It is preferable that the thermoplastic resin has a viscosity of 100 Pa·s or less or a shear modulus of 100 kPa or less at the temperature exceeding the glass transition point.

The laminated body of the Si wafer and the resin sealing body 13 in the heated state is moved onto an insulation plate of normal temperature and naturally cooled on it. For example, the glass transition point of the sealing resin layer 12 is 160° C., the thermal expansion coefficient is 33 ppm at a temperature of the glass transition point or more, and the thermal expansion coefficient is 7 ppm at a temperature of the glass transition point or less. Therefore, the sealing resin layer 12 shrinks considerably while it is being cooled. The glass transition point of the sealing resin layer 12 is preferably in a range of 120 to 170° C., and it is preferable that the thermal expansion coefficient at a temperature of the glass transition point or more is in a range of 30 to 60 ppm, and the thermal expansion coefficient at a temperature of less than the glass transition point is in a range of 6 to 30 ppm.

The resin sealing body 13 including the sealing resin layer 12 is adhered to the separation layer 2 which is formed of the thermoplastic resin layer, so that when the sealing resin layer 12 shrinks, a stress generates in a direction opposite to the support substrate (Si wafer) 1. Therefore, the support substrate (Si wafer) 1 peels from the outer periphery of the resin sealing body 13 at a temperature of the glass transition point or more of the thermoplastic resin. By using a difference in thermal expansion coefficient between the sealing resin layer 12 and the support substrate (Si wafer) 1, the support substrate 1 may be separated from the resin sealing body 13 by a thermal stress generated in the cooling step after heating. This method requires the hot plate only to separate the support substrate 1, and since the need for a large apparatus, a suction mechanism or the like can also be eliminated, it becomes possible to separate the support substrate 1 from the resin sealing body 13 at low cost.

A laser beam or ultraviolet light can also be used in the separation step of the support substrate 1 from the resin sealing body 13. For example, a glass substrate is used as the support substrate 1, the separation layer 2 is formed of a resin material which decomposes upon absorbing the laser beam or ultraviolet light, and the laser beam or ultraviolet light is irradiated to the separation layer 2 via the glass substrate. Since the separation layer 2 decomposes upon absorbing the laser beam or ultraviolet light, the support substrate 1 can be separated from the resin sealing body 13. It is appropriate when at least a portion of the separation layer 2 which forms the interface with the resin sealing body 13 decomposes when the laser beam or ultraviolet light is irradiated. The forming material for the separation layer 2 includes a thermoplastic resin having ability to absorb the laser beam or ultraviolet light. The separation layer 2 has preferably a thickness in a range of 1 to 20 μm.

In order to separate the support substrate 1 by irradiating the laser beam or ultraviolet light to the separation layer 2, the peeling or damage of the wiring layers 3 due to a local temperature increase caused when the laser beam or ultraviolet light is irradiated can be suppressed because the edge surfaces of the wiring layers 3 are covered by the sealing resin layer 12. If the edge surfaces of the wiring layers 3 are not covered by the sealing resin layer 12, a local stress is applied to the organic insulating film 4 of the wiring layers 3 due to the local temperature increase, and the wiring layers 3 might be caused to peel. But, the stress due to the local temperature increase can be dispersed by covering the edge surfaces of the wiring layers 3 by the sealing resin layer 12 and also dividing the wiring layers 3. Thus, it becomes possible to suppress the wiring layers 3 from being peeled or damaged when the support substrate 1 is separated.

When the separation layer 2 is sheared to separate the support substrate 1, a residual layer 2a of the separation layer 2 generates on the first surface 3a of the wiring layer 3 as shown in FIG. 10B. Therefore, the residual layer 2a of the thermoplastic resin is removed by a solvent such as acetone as shown in FIG. 2B and FIG. 10C. The solvent may also configure the thermoplastic resin. The connection portions (such as Cu electrodes) 8a can be exposed on the first surface 3a of the wiring layer 3 by removing the residual layer 2a of the thermoplastic resin and also removing the seed layer 6 exposed on the first surface 3a of the wiring layer 3 by etching.

If the separation layer 2 (may be the mixed layer of the separation layer 2 with the organic insulating film 4 or the sealing resin layer 12) remains partly on the first surface 3a (excepting the exposed portions of the connection portions 8a) of the wiring layer 3, the adhesiveness with the resin to be formed next becomes good, and the reliability of the semiconductor device can be improved. The mixed layer of the organic insulating film 4 and the separation layer 2 which is on the first surface 3a of the wiring layer 3 will be described in detail in a second embodiment. In the first embodiment, it is also preferable to have the mixed layer of the separation layer 2 and the organic insulating film 4 on the first surface 3a of the wiring layer 3 excepting the exposed portions of the connection portions 8a in the same manner as in the second embodiment. Thus, the reliability of the semiconductor device can be improved.

The resin sealing body 13 separated from the support substrate 1 is then cut along the dicing regions by a blade 19 as shown in FIG. 2C to singulate a structure (semiconductor device) 20 having the wiring layer 3, the semiconductor chip 9 and the sealing resin layer 12. When the resin sealing body 13 is cut off, the wiring layer 3 is not damaged and does not peel off because only the sealing resin layer 12 is present at the cutoff portions of the resin sealing body 13. And, it also contributes to the improvement or the like of the reliability at the time of the TCT of the semiconductor devices.

In the structure 20 provided with the wiring layer 3, the semiconductor chip 9 and the sealing resin layer 12, a width of the sealing resin layer 12 formed at the outer periphery portion of the wiring layer 3, namely the distance between edge surface of the wiring layer 3 and the outer periphery surface of the sealing resin layer 12 is preferably determined to be 50 μm or less. It is more preferable that the distance between the edge surface of the wiring layer 3 and the outer periphery surface of the sealing resin layer 12 is 30 μm or less. If the distance between the edge surface of the wiring layer 3 and the outer periphery surface of the sealing resin layer 12 is excessively large, an effective area of the wiring layer 3 decreases, and the semiconductor device becomes large.

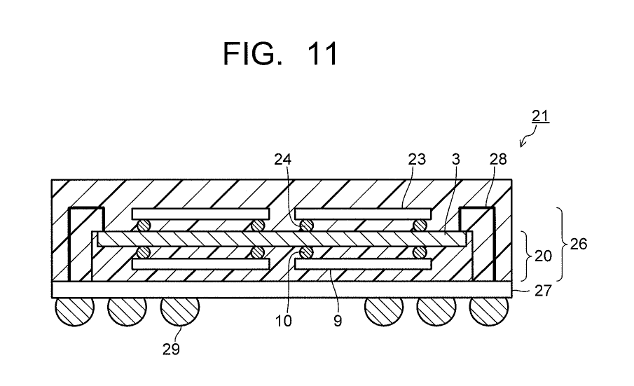

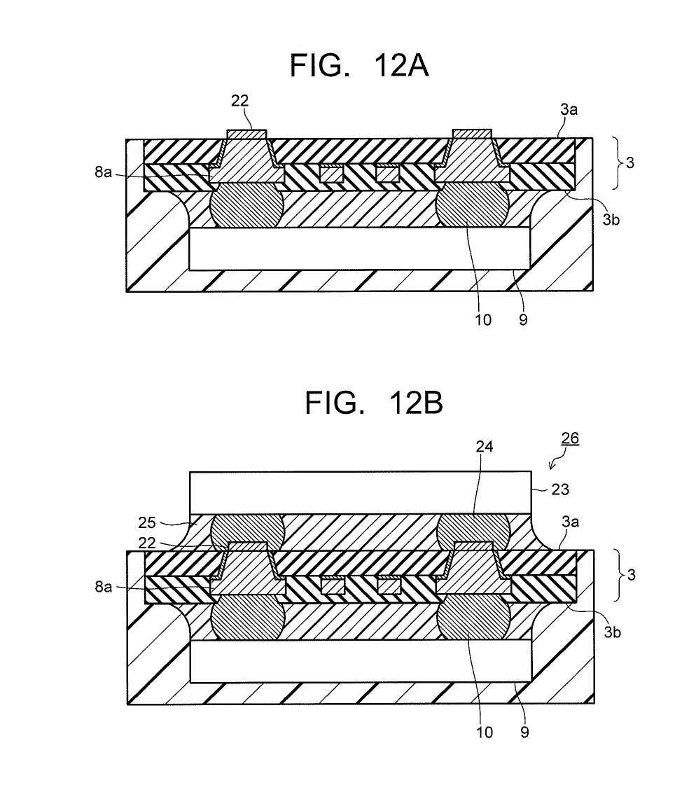

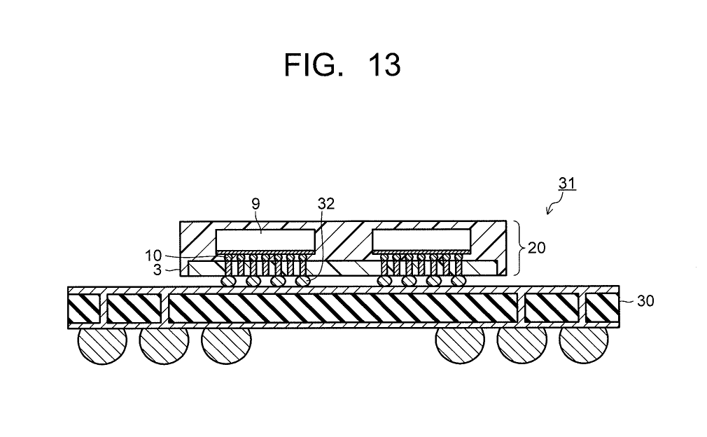

The semiconductor device 20 manufactured through the above-described manufacturing process is used as, for example, a component part of the double-sided mount type semiconductor package (semiconductor part) 21 as shown in FIG. 11. A manufacturing step of the double-sided mount type semiconductor package 21 shown in FIG. 11 is described with reference to FIG. 12. First, a Ni/Pd/Au laminated film 22 is formed if necessary, on the connection portions (such as Cu electrodes) 8a exposed on the first surface 3a of the wiring layer 3 as shown in FIG. 12A. A second semiconductor chip 23 is FC-mounted on the first surface 3a of the wiring layer 3 as shown in FIG. 12B. In other words, metal bumps 24 of the semiconductor chip 23 are FC-connected to the connection portions 8a. An underfill resin 25 may be filled between the second semiconductor chip 23 and the wiring layer 3.

A semiconductor device 26 having the semiconductor chips 9 and 23 mounted on both sides of the wiring layer 3 is configured because the first semiconductor chip 9 is mounted on the second surface 3b of the wiring layer 3. Then, the double-sided mount type semiconductor device 26 is mounted on a package substrate 27 by using a mount paste, and the semiconductor device 26 and the package substrate 27 are electrically connected through bonding wires (such as Au wires) 28. In addition, resin molding is performed to seal the semiconductor chip 23, and metal balls are mounted on the rear surface of the package substrate 27 to form outside connection terminals 29. Thus, the double-sided mount type semiconductor package 21 is completed.

The semiconductor package 21 manufactured according to the above-described manufacturing process is provided to a temperature cycle test (TCT) to examine its reliability. The temperature cycle test was performed with −55° C. (30 minutes)→25° C. (5 minutes)→125° C. (30 minutes) determined as one cycle. As a result, no occurrence of rupture was recognized at the FC-connected portions of each surface of the double-sided mount type semiconductor device 26 after 3000 cycles. The stress applied to the connection portions 8a becomes small because the connection portions 8a formed on the wiring layer 3 become smaller toward the separation layer 2 and the wiring layer 3 is suppressed from expanding and contracting by covering the outer periphery of the wiring layer 3 by the sealing resin layer 12. Thus, the connection portions 8a and the solder bumps 10 and 24 can be suppressed from breaking at the time of the TCT.

As shown in FIG. 13, it is also possible to produce a one-sided mount type semiconductor package (semiconductor part) 31 by mounting the semiconductor device 20 on a package substrate 30. The semiconductor package 31 is produced as follows. First, metal bumps 32 are formed on the connection portions (such as Cu electrodes) 8a which are exposed on the first surface 3a of the wiring layer 3. The semiconductor device 20, on which the metal bumps 32 are formed, is FC-mounted on the package substrate 30 to produce the semiconductor package 31. An underfill resin may also be filled between the semiconductor device 20 and the package substrate 30, and the entire semiconductor device 20 may be resin molded. When the semiconductor package 31 was undergone the TCT, the generation of breakage at the FC-connected portions was not recognized. And, it is also based on the shapes of the sealing resin layer 12 and the connection portions 8a.

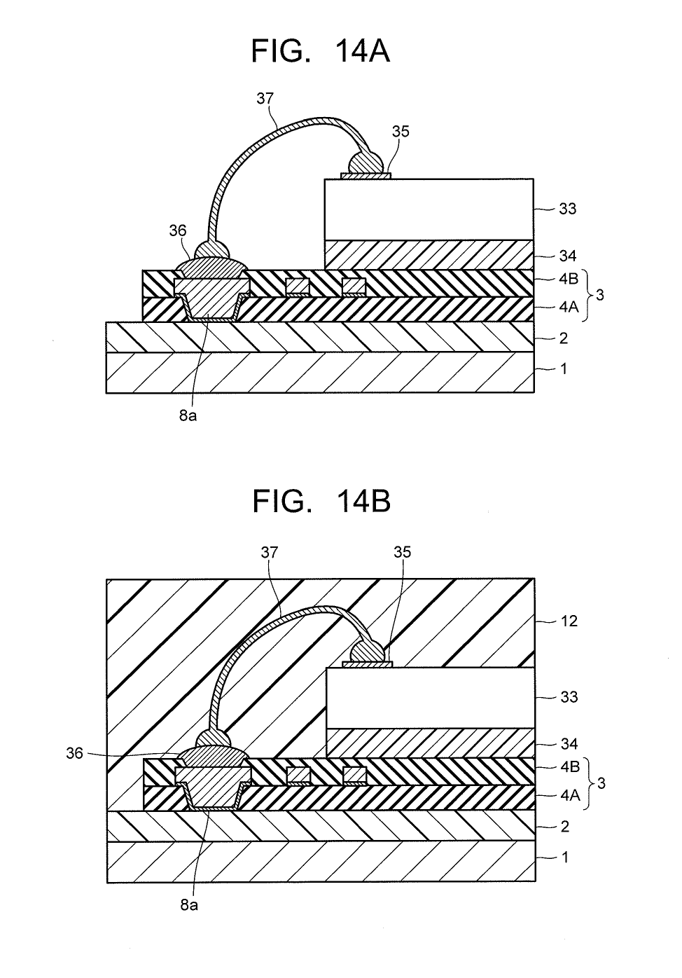

In the manufacturing method of the embodiment, an example of the FC connection of the wiring layer 3 and the semiconductor chip 9 was described. The wiring layer 3 and the semiconductor chip 9 can also be connected electrically by applying wire bonding. That is, a semiconductor chip 33 formed to have a thickness of, for example, about 50 μm is mounted on the wiring layer 3 by a mount material 34 as shown in FIG. 14A. The organic insulating film 4 of the wiring layer 3 is formed on only the device forming region as described above and not on the dicing regions. The semiconductor chip 33 may be stacked into multiple layers. An electrode pad (Al pad) 35 of the semiconductor chip 33 and the connection portion 8a of the wiring layer 3 (via the Ni/Pd/Au laminated film 36 if necessary) are electrically connected through a metal wire 37. And, the sealing resin layer 12 is formed on the separation layer 2 as shown in FIG. 14B. Other steps are performed in the same manner as the semiconductor device manufacturing process that the semiconductor chip 9 is FC-connected.

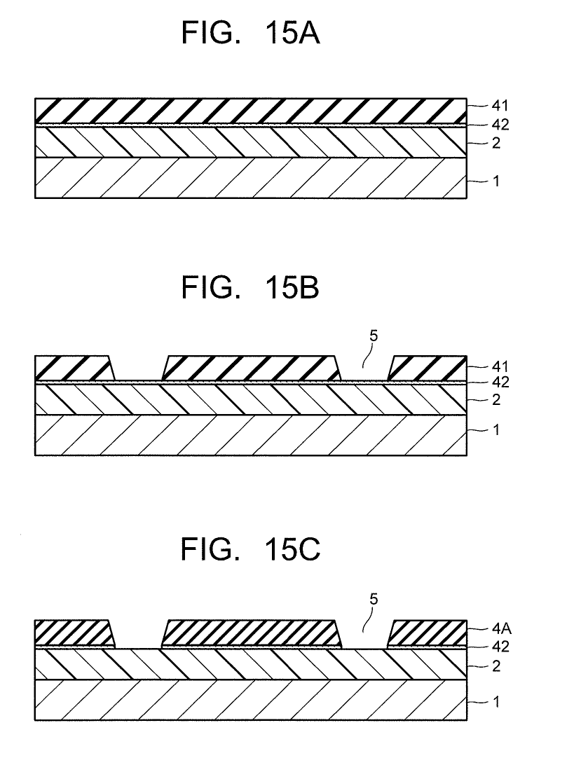

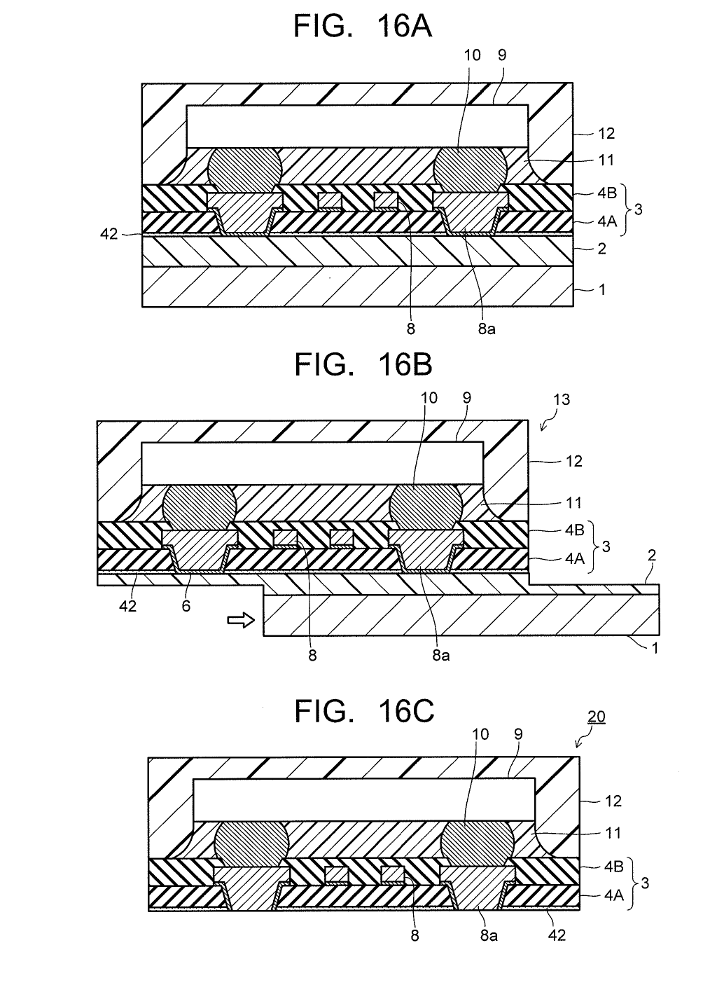

The manufacturing method of the semiconductor device according to the second embodiment is described below with reference to FIG. 15 and FIG. 16. Descriptions and illustration on like component parts corresponding to those of the manufacturing method of the semiconductor device according to the first embodiment are partly omitted. As shown in FIG. 15A, the separation layer 2 formed of a resin material is first formed on the support substrate 1, and a coating film 41 of a thermosetting organic insulating material (such as polyimide resin, polybenzoxazole resin, or phenol resin) which becomes the first organic insulating film 4A is formed. The support substrate 1 and the separation layer 2 have the same structure as in the first embodiment. A mixed layer 42 of the separation layer 2 and the organic insulating material is occasionally formed between the separation layer 2 and the organic insulating film 4A depending on the types and forming methods of them.

As shown in FIG. 15B, the opening portions 5 are then formed by performing the exposure and development treatment of the coating film 41 of the organic insulating material. The mixed layer 42 formed between the separation layer 2 and the coating film 41 of the organic insulating material is exposed in the opening portions 5. When the coating film 41 of the organic insulating material is undergone a curing treatment in a state that the mixed layer 42 is present in the opening portions 5, there is a possibility that a degree of taper of the wall surface of the opening portions 5 becomes excessively gentle. Thus, the opening diameter of the opening portions 5 increases excessively toward the front surface, possibly causing various disadvantages (such as a defective shape of the opening portions 5). Since the mixed layer 42 in the opening portions 5 is an insulating film, it becomes a cause of preventing the exposure of the connection portions 8a.

Therefore, the mixed layer 42 in the opening portions 5 is removed before the curing treatment of the coating film 41 of the organic insulating material. The mixed layer 42 in the opening portions 5 is removed by, for example, dry etching or wet etching. For the dry etching, an aching device is used, and an O₂ asher or the like is applied to remove the mixed layer 42. Etching conditions are selected such that the coating film 41 of the organic insulating material is left remained. Otherwise, etching may be performed under conditions that an etching rate of the mixed layer 42 becomes faster than that of the coating film 41 of the organic insulating material. Then, the coating film 41 of the organic insulating material is undergone a curing treatment to form the first organic insulating film 4A having the opening portions 5 as shown in FIG. 15C.

The above-described first organic insulating film 4A is used to form the wiring layer 3 in the same manner as in the first embodiment. Then, the semiconductor chip 9 is FC-mounted on the wiring layer 3 in the same manner as in the first embodiment, and the underfill resin 11 and the sealing resin layer 12 are additionally formed (FIG. 16A). Then, the support substrate 1 is separated from the resin sealing body 13 in the same manner as in the first embodiment (FIG. 16B). Since a residue of the separation layer 2 generates on the first surface 3a of the wiring layer 3, it is removed by a solvent such as acetone, and the seed layer 6 exposed on the first surface 3a of the wiring layer 3 is etched to expose the connection portions (such as Cu electrodes) 8a on the first surface 3a of the wiring layer 3.

And, the resin sealing body 13 is cut off for individuating in the same manner as in the first embodiment to produce a structure (semiconductor device) 20 having the wiring layer 3, the semiconductor chip 9 and the sealing resin layer 12 (FIG. 16C). To perform the separating step of the support substrate 1 and the cutting step of the resin sealing body 13, it is preferable to apply the same structure (such as the shapes of the wiring layer 3 and the sealing resin layer 12) as in the first embodiment. Similar to the first embodiment, the semiconductor device 20 according to the second embodiment is used as a component part of the double-sided mount type semiconductor package 21 (FIG. 11) or used to produce the one-sided mount type semiconductor package 31 (FIG. 13).

In the semiconductor device 20 according to the second embodiment, the mixed layer 42 of the separation layer 2 and the organic insulating film material improves their adhesion strength. Therefore, delamination in a reflow step or TCT can be suppressed. A defective shape of the opening portions 5 can be suppressed from occurring because the mixed layer 42 in the opening portions 5 is removed previously. And, the front surfaces of the connection portions 8a can be exposed easily by removing the residue of the separation layer 2 after the separating step of the support substrate 1. In addition, since the mixed layer 42 is on the first surface 3a of the wiring layer 3 excepting the exposed surfaces of the connection portions 8a, it becomes possible to improve adhesiveness when another resin layer is formed later.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
forming on a support substrate a separation layer formed of a resin material;
forming on the separation layer a wiring layer which is comprised of an organic insulating film having plural device forming regions and regions corresponding to dicing regions for dividing the plural device forming regions, and metal wirings which are formed on the plural device forming regions of the organic insulating film;
removing the regions corresponding to the dicing regions of the organic insulating film;
mounting plural semiconductor chips on the wiring layer to arrange them on the plural device forming regions;
forming a sealing resin layer for sealing at least part of each of the plural semiconductor chips on the separation layer to cover an edge surface of each of the plural device forming regions of the wiring layer;
separating the support substrate from a resin sealing body which has the wiring layer, the plural semiconductor chips and the sealing resin layer; and
cutting the resin sealing body according to the dicing regions to singulate a structure having the wiring layer, the semiconductor chip and the sealing resin layer.

2. The manufacturing method according to claim 1,
wherein the support substrate is separated from the resin sealing body by heating the separation layer formed of a thermoplastic resin.

3. The manufacturing method according to claim 2,
wherein the support substrate is separated from the resin sealing body by shearing the separation layer softened by the heating.

4. The manufacturing method according to claim 2,
wherein the support substrate is separated from the resin sealing body by a stress generated at the time of the heating or the subsequent cooling based on a difference of thermal expansion coefficient between the support substrate and the sealing resin layer.

5. The manufacturing method according to claim 2,
wherein the thermoplastic resin comprises at least one selected from polyethylene, polypropylene, polystyrene, aclylonitrile styrene resin, aclylonitrile butadiene styrene resin, methacrylate resin, polyamide, polyacetal, polyethylene terephthalate, ultra high molecular weight polyethylene, polybutylene terephthalate, methylpentene, polycarbonate, polyphenylene sulfide, polyether ether ketone, liquid crystalline polymer, polytetrafluoroethylene, polyether imide, polyalylate, polysulfone, polyether sulfone, polyamide imide, cellulose resin, and polyimide.

6. The manufacturing method according to claim 1,
wherein the separation layer has a thickness in a range from 1 to 20 μm.

7. The manufacturing method according to claim 1,
wherein the metal wiring has a connection portion penetrating through the organic insulating film.

8. The manufacturing method according to claim 1,
wherein the sealing resin layer is smaller than the separation layer, and an outer periphery of the sealing resin layer is located inside an outer periphery of the separation layer.

9. The manufacturing method according to claim 1,
wherein an alignment portion for the resin sealing body is formed on the sealing resin layer.

10. A method for manufacturing a semiconductor device, comprising:
forming on a support substrate a separation layer formed of a resin material;
coating a thermosetting organic insulating material on the separation layer;
forming an opening portion in a coating film of the thermosetting organic insulating material;
removing a mixed layer of the separation layer and the thermosetting organic insulating material which is formed between the separation layer and the coating film, and is exposed in the opening portion;
curing the coating film of the thermosetting organic insulating material to form an organic insulating film;
forming a metal wiring in at least the opening portion to provide a wiring layer having the organic insulating film and the metal wiring;
mounting a semiconductor chip on the wiring layer;
forming a sealing resin layer on the separation layer to seal at least part of the semiconductor chip; and
separating the support substrate from a resin sealing body having the wiring layer, the semiconductor chip and the sealing resin layer.

11. The manufacturing method according to claim 10,
wherein the support substrate is separated from the resin sealing body by heating the separation layer formed of a thermoplastic resin.

12. The manufacturing method according to claim 11,
wherein the support substrate is separated from the resin sealing body by shearing the separation layer softened by the heating.

13. The manufacturing method of a semiconductor device according to claim 11,
wherein the support substrate is separated from the resin sealing body by a stress generated at the time of the heating or the subsequent cooling based on a difference of thermal expansion coefficient between the support substrate and the sealing resin layer.

14. A semiconductor device, comprising:
a wiring layer including an organic insulating film and a metal wiring, the wiring layer having a first surface which is a surface separated from a support substrate, a second surface opposite to the first surface, and an edge surface;
a semiconductor chip mounted on the second surface of the wiring layer and electrically connected to the metal wiring; and
a sealing resin layer formed on the wiring layer to seal at least part of the semiconductor chip,
wherein the sealing resin layer is formed to cover the edge surface of the wiring layer while exposing the first surface of the wiring layer,
wherein the metal wiring has a connection portion penetrating through the organic insulating film and exposed on the first and second surfaces of the wiring layer.

15. The semiconductor device according to claim 14,
wherein the connection portion has a shape which an outer shape becomes smaller from the second surface toward the first surface of the wiring layer.

16. The semiconductor device according to claim 15,
wherein the connection portion has the shape that a diameter of a portion exposed on the first surface of the wiring layer is smaller in a range from 10 to 50% than that of a portion exposed on the second surface of the wiring layer.

17. The semiconductor device according to claim 14,
wherein the wiring layer has a thickness of 50 μm or less, and a distance between the edge surface of the wiring layer and an outer periphery surface of the sealing resin layer is 50 μm or less.

18. The semiconductor device according to claim 14,
wherein the first surface of the wiring layer excepting a portion which the connection portion is exposed has a mixed layer of the organic insulating film and a separation layer used for separation from the support substrate.

19. A semiconductor device, comprising:
a wiring layer including an organic insulating film and a metal wiring, the wiring layer having a first surface which is a surface separated from a support substrate and a second surface opposite to the first surface;
a semiconductor chip mounted on the second surface of the wiring layer and electrically connected to the metal wiring; and
a sealing resin layer formed on the wiring layer to seal at least part of the semiconductor chip,
wherein the metal wiring has a connection portion penetrating through the organic insulating film and exposed on the first and second surfaces of the wiring layer,
wherein the first surface of the wiring layer excepting a portion which the connection portion is exposed has a mixed layer of the organic insulating film and a separation layer used for separation from the support substrate.

20. The semiconductor device according to claim 19,
wherein the connection portion has a shape which an outer shape becomes smaller from the second surface toward the first surface of the wiring layer.
